(19) United States
(12) Patent Application Publication
(10) Pub. No.: US 2008/0012055 A1
(43) Pub. Date: Jan. 17, 2008

(54) Layout structure of non-volatile memory

(76) Inventors: Jongoh Kim, Hsinchu (TW); Cheng-Jye Liu, Hsinchu (TW)

Correspondence Address: J.C. Patents, Inc., Suite 250, 4 Venture, Irvine, CA, 92618, US

(21) Appl. No.: 11/479,755

(22) Filed: Jun. 29, 2006

(51) Int. Cl. H01L 29/94; H01L 23/52

(52) U.S. Cl. 257/296; 257/758

(57) ABSTRACT

A layout structure for non-volatile memory is described, including a substrate, bit lines in a column direction, transistors as memory cells, word lines in a row direction, bit line contacts and at least two dummy word lines. The substrate has therein an isolation structure that defines an active area. The bit lines are disposed in the substrate in the active area. The transistors are disposed on the substrate between the bit lines and arranged in rows and columns. Each word line is coupled to the transistors in one row. The bit line contacts are disposed on the bit lines. The dummy word lines are disposed on the isolation structure, respectively at two sides of the active area and parallel with the word lines.

### BACKGROUND OF THE INVENTION

1. Field of the Invention

The present invention relates to a semiconductor device layout structure. More particularly, the present invention relates to a layout structure of non-volatile memory.

2. Description of the Related Art

As microprocessors and software get more powerful, higher memory capacity is required. The memory capacity is raised mostly by increasing the integration degree of the memory device, so that the design rule of memory layout becomes narrower.

There are many variation factors in a memory fabricating process that affect the yield and reliability of memory devices. For example, the critical dimension (CD) at edges of a memory array is easily different from that at the center of the same due to the lithographic optics, so that a malfunction like leakage or short circuit is often caused lowering the yield and reliability of the memory device. It is therefore important to uniformize the critical dimension in a memory array.

### SUMMARY OF THE INVENTION

In view of the foregoing, this invention provides a layout structure of non-volatile memory that can improve the CD uniformity.

This invention also provides a layout structure of non-volatile memory that can improve the CD uniformity as well as improve the lithography process window.

A layout structure of non-volatile memory of this invention includes a substrate, bit lines in a column direction, transistors as memory cells, word lines in a row direction, bit line contacts and at least two dummy word lines. The substrate has therein an isolation structure that defines an active area. The bit lines are disposed in the substrate in the active area. The transistors are disposed on the substrate between the bit lines and arranged in rows and columns. Each word line is coupled to the transistors in one row. The at least two dummy word lines are disposed on the isolation structure, respectively at two sides of the active area and parallel with the word lines. The bit line contacts are disposed on portions of the bit lines between the dummy word lines and the word lines.

The layout structure may further include multiple word line contacts that are disposed alternately on a first end and a second end of the word lines. The isolation structure may be a shallow trench isolation (STI) structure or a field oxide (FOX) layer, and each bit line may include a linear doped region. The material of the word lines and the dummy word lines may be doped poly-Si.

Another layout structure of non-volatile memory of this invention includes a substrate, bit lines in a column direction, transistors as memory cells, word lines in a row direction, bit line contacts and at least two dummy word lines. The substrate has therein an isolation structure that defines an active area. The bit lines are disposed in the substrate in the active area. The transistors are disposed on the substrate between the bit lines and arranged in rows and columns. Each word line is coupled to the transistors in one row. The bit line contacts are disposed on portions of the bit lines between the word lines. The at least two dummy word lines are disposed on the isolation structure, respectively at two sides of the active area and parallel with the word lines.

Similarly, the above layout structure may further include multiple word line contacts that are disposed alternately on a first end and a second end of the word lines. The isolation structure may be a shallow trench isolation (STI) structure or a field oxide (FOX) layer, and each bit line may include a linear doped region. The material of the word lines and the dummy word lines may be doped poly-Si.

Since dummy word line patterns are added at two sides of the active area, i.e., beside the word line patterns, the CD difference between the edge portions and the central portion of the memory array can be decreased. Moreover, because the dummy word lines are disposed on the isolation structure but not on the active area, the size of the active area is not increased, and no transistor is formed from the dummy word lines to cause leakage or performance degradation to the device.

It is to be understood that both the foregoing general description and the following detailed description are exemplary, and are intended to provide further explanation of the invention as claimed.

### BRIEF DESCRIPTION OF THE DRAWINGS

FIG. 1 illustrates a top view of a layout structure of non-volatile memory according to an embodiment of this invention.

FIG. 2 illustrates a top view of a layout structure of non-volatile memory according to another embodiment of this invention.

### DESCRIPTION OF THE PREFERRED EMBODIMENTS

It is firstly noted that though each row of transistors/memory cells in the two embodiments illustrated by FIGS. I and 2 includes three transistors/memory cells, the number of transistors/memory cells in each row is not limited to three in this invention.

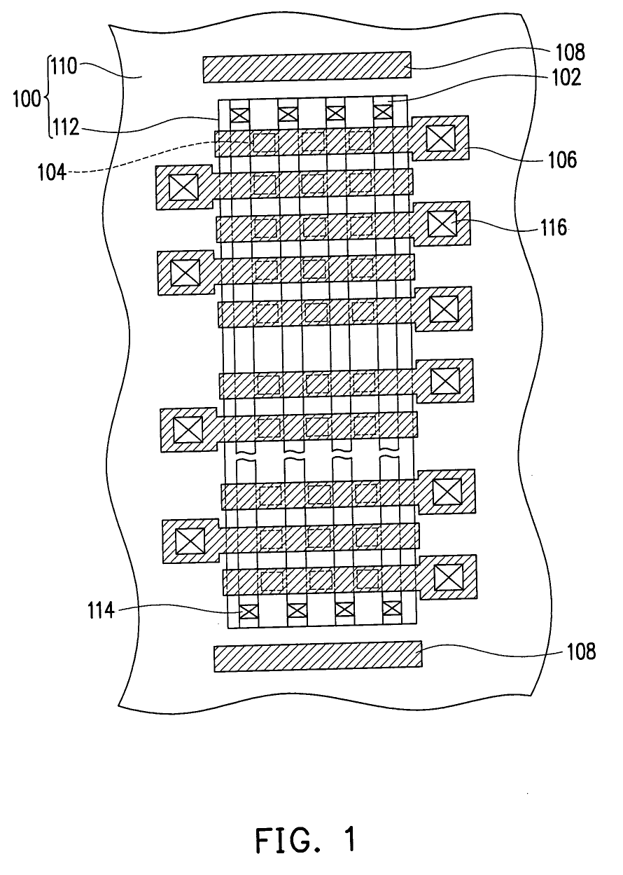

Referring to FIG. 1, the layout structure in this embodiment includes a substrate 100, bit lines 102 in the column direction, transistors 104 as memory cells, word lines 106 in the row direction and at least two dummy word lines 108, wherein the column direction is usually perpendicular to the row direction. The substrate 110 has therein an isolation structure 110, such as an STI structure or a FOX layer, which defines an active area 112. The bit lines 102 are disposed in the substrate 100 in the active area 112, each possibly being a linear doped region. The transistors 104 are disposed on the substrate 100 between the buried bit lines 102 and arranged in rows and columns. Each transistor 104 serves as a memory cell, and may include a gate structure under a word line 106 and a portion of the two adjacent buried bit lines 102 as an S/D region or include a portion of a word line 106 between two buried bit lines 102 and a portion of the two buried bit lines 102 as an S/D region.

Each word line 106 is coupled to the transistors 104 in one row. The bit line contacts 114 are disposed on portions of the buried bit lines 102 at two edges of the active area 112 to electrically connect thereto. The layout structure may further include word line contacts 116 disposed alternately at a first end and a second end of the word lines 106 to electrically connect the word lines 106 to upper metal lines (not shown).

The at least two dummy word lines 108 are disposed on the isolation structure 110, respectively at two sides of the active area 112 and parallel with the word lines 106, while the bit line contacts 114 disposed on portions of the buried bit lines 102 at two edges of the active area 112 are between the dummy word lines 108 and the word lines 106. The material of the word lines 106 and the dummy word lines 108 may be doped poly-Si. The two dummy word lines 108 can prevent CD deviation of the word lines 106 near the edges of the active region 112. Meanwhile, for the dummy word lines 108 are disposed on the isolation structure 110 but not on the active area 112, the size of the active area 112 is not increased, and no transistor is formed from the dummy word lines 108 to cause leakage or performance degradation to the device.

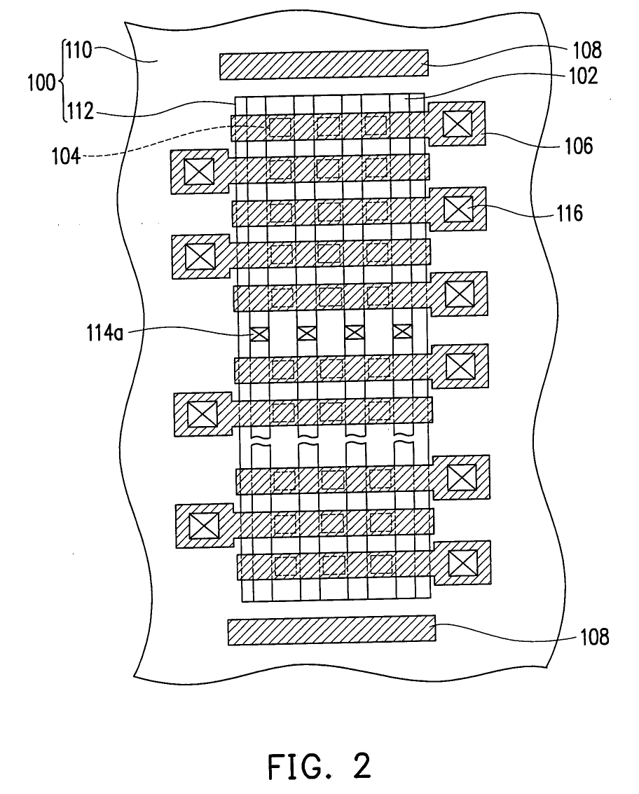

Referring to FIG. 2, the layout structure in this embodiment is different from that in the above embodiment in that the bit line contact 114a are disposed on portions of the buried bit lines 102 between the word lines 106 but not on portions of the buried bit lines 102 between the dummy word lines 108 and the word lines 106, so that the distance between them is reduced to improve the lithography process window.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A layout structure of non-volatile memory, comprising:
a substrate, having therein an isolation structure defining an active area;
a plurality of bit lines in a column direction, disposed in the substrate in the active area;
a plurality of transistors as memory cells, disposed on the substrate between the bit lines and arranged in rows and columns;
a plurality of word lines in a row direction, each coupled to the transistors in one row;
at least two dummy word lines on the isolation structure, respectively at two sides of the active area and parallel with the word lines; and
a plurality of bit line contacts, disposed on portions of the bit lines between the dummy word lines and the word lines.

2. The layout structure of claim 1, further comprising a plurality of word line contacts that are disposed alternately on a first end and a second end of the word lines.

3. The layout structure of claim 1, wherein the isolation structure comprises a shallow trench isolation structure or a field oxide layer.

4. The layout structure of claim 1, wherein each buried bit line includes a linear doped region.

5. The layout structure of claim 1, wherein the word lines and the dummy word lines comprise doped polysilicon.

6. A layout structure of non-volatile memory, comprising:
a substrate, having therein an isolation structure defining an active area;
a plurality of bit lines in a column direction, disposed in the substrate in the active area;
a plurality of transistors as memory cells, disposed on the substrate between the bit lines and arranged in rows and columns;
a plurality of word lines in a row direction, each coupled to the transistors in one row;
a plurality of bit line contacts, disposed on portions of the bit lines between the word lines; and
at least two dummy word lines on the isolation structure, respectively at two sides of the active area and parallel with the word lines.

7. The layout structure of claim 6, further comprising a plurality of word line contacts that are disposed alternately on a first end and a second end of the word lines.

8. The layout structure of claim 6, wherein the isolation structure comprises a shallow trench isolation structure or a field oxide layer.

9. The layout structure of claim 6, wherein each bit line includes a linear doped region.

10. The layout structure of claim 6, wherein the word lines and the dummy word lines comprise doped polysilicon.
